(19) United States
(12) Patent Application Publication
(10) Pub. No.: US 2023/0361744 A1
(43) Pub. Date: Nov. 9, 2023

(54) BAND PASS FILTER AND RECEIVER MODULE

(71) Applicant: SAMSUNG ELECTRO-MECHANICS CO., LTD., Suwon-si (KR)

(72) Inventor: Eunhyuk KWAK, Suwon-si (KR)

(73) Assignee: SAMSUNG ELECTRO-MECHANICS CO., LTD., Suwon-si (KR)

(21) Appl. No.: 18/091,686

(22) Filed: Dec. 30, 2022

(30) Foreign Application Priority Data
May 3, 2022 (KR) 10-2022-0054914
Aug. 17, 2022 (KR) 10-2022-0102620

(51) Int. Cl. H03H 7/01

(52) U.S. Cl. CPC H03H 7/0161; H03H 7/0115; H03H 7/175

(57) ABSTRACT

A band pass filter includes: a resonator including a first inductor and a first capacitor coupled in series between a first port and a second port; a second capacitor coupled in parallel to the resonator; and a third capacitor connected between one end of the second capacitor and the ground to perform a low pass filter function.

### CROSS-REFERENCE TO RELATED APPLICATION

This application claims priority to and the benefit under 35 USC 119(a) of Korean Patent Application No. 10-2022-0054914 filed in the Korean Intellectual Property Office on May 3, 2022, and Korean Patent Application No. 10-2022-0102620 filed in the Korean Intellectual Property Office on Aug. 17, 2022, the entire contents of which are incorporated herein by reference for all purposes.

### BACKGROUND

### Field

The following description relates to a band pass filter and a receiver module including the same.

### Description of the Background

Electronic devices such as mobile phones are required to be down-sized, increase a frequency band used, diversify functions, and strengthen functions. Accordingly, down-sizing of a module mounted on the electronic device and an integrated circuit (IC) constituting the module is also required.

The band pass filter, which is one of the core ICs, also needs to be developed to meet these requirements. Down-sizing of the band pass filter is required. Due to the increase and diversification of a using frequency band, the band pass filter is required to have excellent cut-off characteristics in a band adjacent to the main frequency band. In addition, due to the increase in the using frequency band, the band pass filter is required to have a harmonic frequency attenuation characteristic.

The above information disclosed in this Background section is only for enhancement of understanding of the background of the described technology, and therefore it may contain information that does not form the prior art that is already known in this country to a person of ordinary skill in the art.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a band pass filter includes: a resonator including a first inductor and a first capacitor coupled in series between a first port and a second port; a second capacitor coupled in parallel to the resonator; and a third capacitor connected between one end of the second capacitor and a ground, and configured to perform a low pass filter function.

The band pass filter may further include a fourth capacitor coupled in series with the second capacitor and coupled in parallel with the resonator between the first port and the second port.

The third capacitor may be connected between a contact point of the second capacitor and the fourth capacitor and the ground.

The band pass filter may further include: a fifth capacitor connected between the first port and the ground; and a sixth capacitor connected between the second port and the ground.

The fifth capacitor and the sixth capacitor may be configured to perform the low pass filter function together with the third capacitor.

The band pass filter may further include a fourth capacitor connected between another end of the second capacitor and the ground.

The fourth capacitor may be configured to perform the low pass filter function together with the third capacitor.

The third capacitor may reduce a harmonic frequency component included in a high frequency band in a radio frequency signal input to the first port.

The third capacitor may bypass a high frequency band signal in a radio frequency signal input to the first port to the ground.

In another general aspect, a receiver module includes: a switch integrated circuit (IC) configured to switch a received radio frequency signal; a band pass filter configured to pass a main frequency band in the radio frequency signal transmitted from the switch IC; and a low noise amplifier configured to amplify a signal transmitted from the band pass filter. The band pass filter includes: a resonator including a first inductor and a first capacitor coupled in series between an input port and an output port; a second capacitor connected between the input port and the output port, and coupled in parallel with the resonator; and a third capacitor connected between one end of the second capacitor and a ground, and configured to perform a low pass filter function.

The band pass filter may further include a fourth capacitor coupled in series with the second capacitor between the input port and the output port and coupled in parallel with the resonator, and the third capacitor may be connected between a contact node of the second capacitor and the fourth capacitor and the ground.

The band pass filter may further include a fifth capacitor connected between the input port and the ground, and a sixth capacitor connected between the output port and the ground.

The fifth capacitor and the sixth capacitor may be configured to perform the low pass filter function together with the third capacitor.

The band pass filter may further include a fourth capacitor connected between another end of the second capacitor and the ground.

The fourth capacitor may be configured to perform the low pass filter function together with the third capacitor.

Other features and aspects will be apparent from the following detailed description, the drawings, and the claims.

### BRIEF DESCRIPTION OF THE DRAWINGS

FIG. 1 is a circuit diagram of a band pass filter according to an example.

FIG. 2 is a circuit diagram of a band pass filter according to another example.

FIG. 3 is a circuit diagram that shows a band pass filter according to another example.

FIG. 4 is a circuit diagram of a band pass filter according to another example.

FIG. 5 is a graph that shows a simulation result with respect to the examples and a simulation result with respect to a comparative example.

FIG. 6 is a block diagram of a receiver module according to an example.

Throughout the drawings and the detailed description, the same reference numerals refer to the same elements. The drawings may not be to scale, and the relative size, proportions, and depictions of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that would be well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will fully convey the scope of the disclosure to one of ordinary skill in the art.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

The drawings may not be to scale, and the relative sizes, proportions, and depiction of elements in the drawings may be exaggerated for clarity, illustration, and convenience.

Throughout the specification, radio frequency (RF) signals may have forms such as Wi-Fi (IEEE 802.11 family, etc.), WiMAX (IEEE 802.16 family, etc.), IEEE 802.20, LTE (long term evolution), Ev-DO, HSPA, HSDPA, HSUPA, EDGE, GSM, GPS, GPRS, CDMA, TDMA, DECT, Bluetooth, 3G, 4G, 5G and any other wireless and wired protocols designated thereafter, but are not limited thereto.

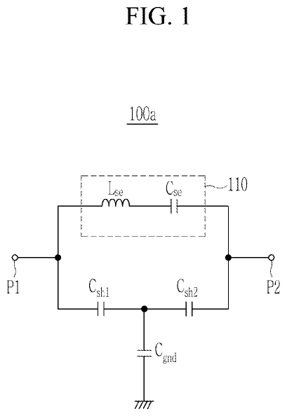

FIG. 1 is a circuit diagram of a band pass filter 100a according to an example.

The band pass filter 100a may pass a main frequency band in an input RF signal. The band pass filter 100a may pass the main frequency band in the input RF signal input to a first port P1 and output it to a second port P2. The band pass filter 100a may pass the main frequency band from the input RF signal to the second port P2 and output it to the first port P1. That is, since the band pass filter 100a has a symmetrical internal configuration, an RF signal may be input to the first port P1 and an RF signal may be input to the second port P2. Here, the main frequency band means a frequency band to be passed by the band pass filter 100a. In the following description, the term “main frequency band” may be used interchangeably with the term “passband”.

As shown in FIG. 1, the band pass filter 100a may include an inductor Lₛₑ, a capacitor Cₛₑ, a capacitor Cₛₕ₁, a capacitor Cₛₕ₂, and a capacitor C_{gnd}.

One end of the inductor Lₛₑ is connected to the first port P1, and the capacitor Cₛₑ may be connected between the other end of the inductor Lₛₑ and the second port P2. The inductor Lₛₑ and the capacitor Cₛₑ are coupled in series between the first port P1 and the second port P2 such that a resonator 110 can be formed. The resonator 110 may perform a function of passing the main frequency band through the LC resonance. The disposal of the inductor Lₛₑ and the capacitor Cₛₑ may be changed (exchanged) with each other.

One end of the capacitor Cₛₕ₁ is connected to the first port P1, and the capacitor Cₛₕ₂ may be connected between the other end of the capacitor Cₛₕ₁ and the second port P2. In one view, the capacitor Cₛₕ₁ is coupled in parallel to the resonator 110, and the capacitor Cₛₕ₂ is also coupled in parallel to the resonator 110. In addition, in another view, the capacitor Cₛₕ₁ and the capacitor Cₛₕ₂ are coupled in series between the first port P1 and the second port P2. The capacitor Cₛₕ₁ and the capacitor Cₛₕ₂ may perform cut-off for an adjacent high frequency band together with the resonator 110. Here, the adjacent high frequency band may mean a frequency band adjacent to the main frequency band and higher than the main frequency band.

The capacitor C_{gnd} may be connected between the ground and a contact point between the capacitor Cₛₕ₁ and the capacitor Cₛₕ₂. That is, the capacitor C_{gnd} may be connected between the other end of the capacitor Cₛₕ₁ and the ground. The capacitor C_{gnd} may serve to reduce harmonic frequency components. Since the capacitor C_{gnd} is connected to the ground between the first port P1 and the second port P2, the capacitor C_{gnd} serves as a low pass filter (LPF). That is, the capacitor C_{gnd} may pass a low passband in an input RF signal and may bypass a high frequency band. Accordingly, harmonic frequency components included in the high frequency band may be reduced. In another view, the capacitor C_{gnd}, the capacitor Cₛₕ₁, and the capacitor Cₛₕ₂ may cut off an adjacent high frequency band together with the resonator 110.

In the band pass filter 100a, a center frequency f_{z} of the main frequency band (passband) may be represented as given in Equation 1.

$${f}_{z} = \frac{1}{2 π \sqrt{{L}_{se} {C}_{se}}} \qquad ( Equation 1 )$$

As shown in Equation 1, the center frequency f_{z} of the main frequency band (passband) may be determined by two elements Lₛₑ and Cₛₑ included in the resonator 110.

In the band pass filter 100a, a center frequency fₚ of a cut-off band may be represented as given in Equation 2.

$${f}_{p} = \frac{1}{2 π \sqrt{{L}_{se} {C}_{eq}}} \qquad ( Equation 2 )$$

In Equation 2, C_{eq} indicates an equivalent capacitor with respect to the capacitor Cₛₑ, the capacitor Cₛₕ₁, the capacitor Cₛₕ₂, and the capacitor C_{gnd}. As shown in Equation 2, a center frequency fₚ of the cut-off band may be determined by the inductor Lₛₑ and the equivalent capacitor C_{eq}.

Referring to FIG. 1, the elements included in the band pass filter 100a are arranged symmetrically with each other between the first port P1 and the second port P2. That is, the capacitor Cₛₕ₁, the capacitor Cₛₕ₂, and the capacitor C_{gnd} are arranged symmetrically with each other. Accordingly, the band pass filter 100a may have the same input impedance and output impedance. In other words, in the band pass filter 100a, the impedance at the first port P1 and the impedance at the second port P2 may be the same.

The band pass filter 100a may reduce the number of inductor elements compared to the existing band pass filter, and thus it is advantageous for down-sizing. When implementing inductors and capacitors using semiconductor processes such as an integrated passive device (IPD), inductors occupy a larger space than capacitors. As shown in FIG. 1, the band pass filter 100a can be implemented substantially through one inductor Lₛₑ, and thus it can be down-sized.

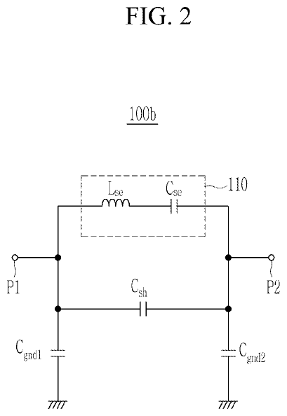

The capacitor Cₛₕ₁, the capacitor Cₛₕ₂, and the capacitor C_{gnd} in FIG. 1 may be deformed in various shapes while forming a symmetric structure with each other, and this will be described hereinafter with reference to FIG. 2 to FIG. 5.

FIG. 2 is a circuit diagram of a band pass filter 100b according to another example.

As shown in FIG. 2, a band pass filter 100b may include an inductor Lₛₑ, a capacitor Cₛₑ, a capacitor Cₛₕ, a capacitor C_{gnd1} and a capacitor C_{gnd2}.

The band pass filter 100b of FIG. 2 is substantially the same as the band pass filter 100a of FIG. 1, except that a symmetrical arrangement structure of the capacitor Cₛₕ the capacitor C_{gnd1} and the capacitor C_{gnd2} is changed. The capacitor Cₛₕ₁ and the capacitor Cₛₕ₂ of FIG. 1 are integrated to the capacitor Cₛₕ, and the capacitor C_{gnd} of FIG. 1 is separated into two capacitors C_{gnd1} and C_{gnd2}.

One end of the capacitor Cₛₕ may be connected to a first port P1, and the other end of the capacitor Cₛₕ may be connected to a second port P2. That is, the capacitor Cₛₕ may be coupled in parallel to a resonator 110. The capacitor Cₛₕ may cut off an adjacent high frequency band together with the resonator 110.

The capacitor C_{gnd1} may be connected between one end (i.e., first port P1) of the capacitor Cₛₕ and the ground, and the capacitor C_{gnd2} may be connected between the other end (i.e., second port P2) of the capacitor Cₛₕ and the ground. The capacitor C_{gnd1} and the capacitor C_{gnd2} may serve to reduce a harmonic frequency component. Since the capacitor C_{gnd1} and the capacitor C_{gnd2} are connected to the ground respectively between the first port P1 and the second port P2, they serve as low pass filters (LPF). That is, the capacitor C_{gnd1} and the capacitor C_{gnd2} may pass a low frequency band in an input RF signal and may bypass a high frequency band to the ground. Accordingly, a harmonic frequency component included in the high frequency band may be reduced. In another view, the capacitor C_{gnd1} the capacitor C_{gnd2}, and the capacitor Cₛₕ may cut off an adjacent high frequency band together with the resonator 110.

In the band pass filter 100b, a center frequency f_{z} of the main frequency band (passband) is substantially the same as in Equation 1.

In the band pass filter 100b, a center frequency fₚ of a cut-off band is substantially the same as in Equation 2. However, in Equation 2, C_{eq} may be replaced with an equivalent capacitor with respect to the capacitor Cₛₑ, the capacitor Cₛₕ, the capacitor C_{gnd1} and the capacitor C_{gnd2}.

Between the first port P1 and the second port P2, the capacitor Cₛₕ, the capacitor C_{gnd1} and the capacitor C_{gnd2} are arranged symmetrically with each other. Accordingly, the band pass filter 100b may also have the same input impedance and output impedance.

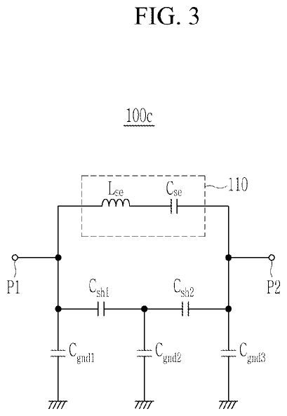

FIG. 3 is a circuit diagram that shows a band pass filter 100c according to another example.

As shown in FIG. 3, a band pass filter 100c may include an inductor Lₛₑ, a capacitor Cₛₑ, a capacitor Cₛₕ₁, a capacitor Cₛₕ₂, a capacitor C_{gnd1} a capacitor C_{gnd2}, and a capacitor C_{gnd3}.

The band pass filter 100c of FIG. 3 is substantially equivalent to the band pass filter of FIG. 1, except that a capacitor C_{gnd1} and a capacitor C_{gnd3} that perform an LPF function are added. The capacitor C_{gnd} of FIG. 1 may be separated into three capacitors C_{gnd1}, C_{gnd2}, and C_{gnd3}.

One end of the capacitor C_{gnd1} may be connected between one end (i.e., a first port P1) of the capacitor Cₛₕ₁ and the ground. The capacitor C_{gnd2} may be connected between a contact point between the capacitor Cₛₕ₁ and the capacitor Cₛₕ₂ and the ground. That is, the capacitor C_{gnd2} may be connected between the other end of the capacitor Cₛₕ₁ and the ground. In addition, the capacitor C_{gnd3} may be connected between the second port P2 and the ground. The capacitor C_{gnd1} the capacitor C_{gnd2}, and the capacitor C_{gnd3} may reduce a harmonic frequency component. Since the capacitor C_{gnd1} the capacitor C_{gnd2}, and the capacitor C_{gnd3} are respectively connected to the ground between the first port P1 and the second port P2, they perform a low pass filter (LPF) function. That is, the capacitor C_{gnd1} the capacitor C_{gnd2}, and the capacitor C_{gnd3} may pass a low frequency band in an input RF signal and bypass a high frequency band to the ground. Accordingly, harmonic components included in the high frequency band may be reduced. In other view, the capacitor C_{gnd1} the capacitor C_{gnd2}, the capacitor C_{gnd3}, the capacitor Cₛₕ₁, and the capacitor Cₛₕ₂ may cut off an adjacent high frequency band together with the resonator 110.

In the band pass filter 100c, a center frequency fₚ of the main frequency band (passband) is substantially the same as Equation 1.

In the band pass filter 100c, a center frequency fₚ of a cut-off band is substantially the same as Equation 2. However, in Equation 2, C_{eq} may be replaced with an equivalent capacitor with respect to the capacitor Cₛₑ, the capacitor Cₛₕ₁, the capacitor Cₛₕ₂, the capacitor C_{gnd1}, the capacitor C_{gnd2}, and the capacitor C_{gnd3}.

The capacitor Cₛₕ₁, the capacitor Cₛₕ₂, the capacitor C_{gnd1}, the capacitor C_{gnd2}, and the capacitor C_{gnd3} are arranged symmetrically with each other between the first port P1 and the second port P2. Accordingly, the band pass filter 100c may also have the same input impedance and output impedance.

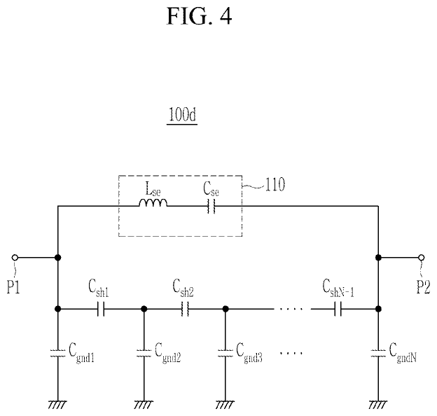

FIG. 4 is a circuit diagram of a band pass filter 100d according to another example.

As shown in FIG. 4, a band pass filter 100d may include an inductor Lₛₑ, a capacitor Cₛₑ, a capacitor Cₛₕ₁ to a capacitor C_{(shN-1)}, a capacitor C_{gnd1}, a capacitor C_{gnd2}, and a capacitor C_{gnd3} to a capacitor C_{gndN}. Here, N may be a natural number of 4 or more.

The band pass filter 100d of FIG. 4 is the same as the band pass filter 100c of FIG. 3 except that the capacitors Cₛₕ₁ and Cₛₕ₂ and the capacitors C_{gn1}, C_{gn2}, and C_{gn3} of the band pass filter 100c are expanded to N number of capacitors.

The capacitor C_{gnd1}, the capacitor C_{gnd2}, and the capacitor C_{gnd3} to the capacitor C_{gndN} may reduce a harmonic frequency component. Since the capacitor C_{gnd1}, the capacitor C_{gnd2}, and the capacitor C_{gnd3} to the capacitor C_{gndN} are connected to the ground between a first port P1 and a second port P2, they perform a low pass filter (LPF) function. That is, the capacitor C_{gnd1}, the capacitor C_{gnd2}, and the capacitor C_{gnd3} to the capacitor C_{gndN} pass a low frequency band in an input RF signal and bypass a high frequency band. Accordingly, harmonic components included in the high frequency band may be reduced. In another view, the capacitor C_{gnd1}, the capacitor C_{gnd2}, the capacitor C_{gnd3} to the capacitor C_{gndN}, the capacitor Cₛₕ₁, and the capacitor Cₛₕ₂ to the capacitor C_{(shN-1)} may cut off an adjacent high frequency band together with a resonator 110. The low frequency passband and harmonic reduction characteristics may be determined by capacitors formed of the capacitor C_{gnd1}, the capacitor C_{gnd2}, and the capacitor C_{gnd3} to the capacitors C_{gndN}. Here, as the time constant of each of the capacitors C_{gnd1}, C_{gnd2}, C_{gnd3}, . . . , and C_{gndN}, and N, are high, the harmonic reduction characteristic can be more improved. Meanwhile, for the target harmonic reduction characteristic, the number of capacitors (C_{gnd1}, C_{gnd2}, C_{gnd3}, . . . , and C_{gndN}) performing a low-frequency bandpass function may be adjusted.

In the band pass filter 100d, a center frequency f_{z} of the main frequency band (passband) is substantially the same as Equation 1.

In the band pass filter 100d, a center frequency fₚ of a cut-off band is substantially the same as Equation 2. However, in Equation 2, C_{eq} may be replaced with an equivalent capacitor with respect to the capacitor Cₛₑ, the capacitor Cₛₕ₁, the capacitor Cₛₕ₂ to capacitor C_{shN-1}, the capacitor C_{gnd1}, the capacitor C_{gnd2}, and the capacitor C_{gnd3} to capacitor C_{gndN}.

The capacitor Cₛₑ, the capacitor Cₛₕ₁, the capacitor Cₛₕ₂ to capacitor C_{shN-1}, the capacitor C_{gnd1}, the capacitor C_{gnd2}, and the capacitor C_{gnd3} to capacitor C_{gndN} are arranged symmetrically with each other between the first port P1 and the second port P2. Accordingly, the band pass filter 100d may also have the same input impedance and output impedance.

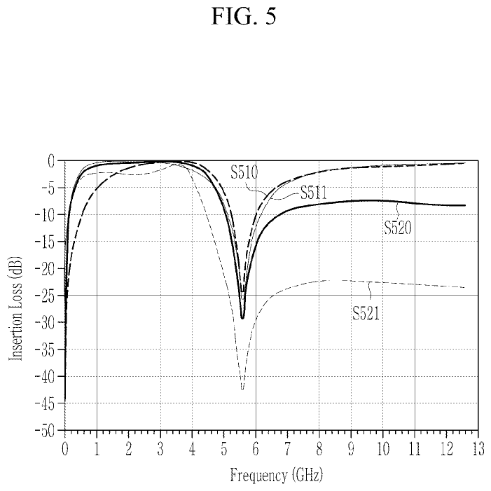

FIG. 5 is a graph that shows a simulation result with respect to the above-described examples and a simulation result with respect to a comparative example.

In FIGS. 5, S510 and S511 show simulation results of a comparative example. S520 shows a simulation result of the band pass filter 100a of FIGS. 1, and S521 shows a simulation result of the band pass filter 100c of FIG. 3. Here, the comparative example is a band pass filter that is disclosed in the reference document “Jianhua Deng et al. Compact LTCC Bandpass Filter Design with Controllable Transmission Zeros in the Stopband. Microwave and optical technology letters. Vol. 48. No. 11. 2261-2263 2006”. In FIG. 5, the horizontal axis represents a frequency, and the vertical axis represents an insertion loss (parameter S21).

Referring to FIG. 5, both of the examples and the comparative example have a cutoff characteristic in a low frequency band and have a 3 GHz band pass and a 5.5 GHz cutoff characteristic. The examples S520 and S521 are more excellent than the comparative examples S510 and S511 in the 5.5 GHz cut-off characteristic and the harmonic reduction characteristic of 6 GHz or more.

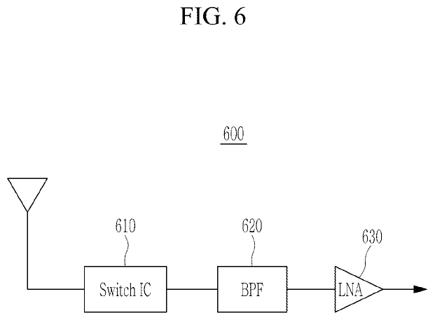

FIG. 6 is a block diagram of a receiver module 600 according to an example.

As shown in FIG. 6, a receiver module 600 may include a switch integrated circuit (IC) 610, a band pass filter 620, and a low noise amplifier (LNA) 630.

The switch IC 610 may include at least one switch and may switch an RF signal received through an antenna to the band pass filter 620. Here, the switch IC 610 may separate and switch a transmitted RF signal and a received RF signal.

The band pass filter 620 may pass a main frequency band in the RF signal transmitted from the switch IC 610. Here, the band pass filter 620 may be any one of the band pass filter 100a of FIG. 1, the band pass filter 100b of FIG. 2, the band pass filter 100c of FIG. 3, and the band pass filter 100d of FIG. 4.

The low noise amplifier 630 may amplify the RF signal filtered by the band pass filter 620. Since the received RF signal may be weak, the low noise amplifier 630 amplifies the received RF signal.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed to have a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A band pass filter comprising:
a resonator including a first inductor and a first capacitor coupled in series between a first port and a second port;
a second capacitor coupled in parallel to the resonator; and
a third capacitor connected between one end of the second capacitor and a ground, and configured to perform a low pass filter function.

2. The band pass filter of claim 1, further comprising a fourth capacitor coupled in series with the second capacitor and coupled in parallel with the resonator between the first port and the second port.

3. The band pass filter of claim 2, wherein
the third capacitor is connected between a contact point of the second capacitor and the fourth capacitor and the ground.

4. The band pass filter of claim 3, further comprising:
a fifth capacitor connected between the first port and the ground; and
a sixth capacitor connected between the second port and the ground.

5. The band pass filter of claim 4, wherein
the fifth capacitor and the sixth capacitor are configured to perform the low pass filter function together with the third capacitor.

6. The band pass filter of claim 1, further comprising a fourth capacitor connected between another end of the second capacitor and the ground.

7. The band pass filter of claim 6, wherein
the fourth capacitor is configured to perform the low pass filter function together with the third capacitor.

8. The band pass filter of claim 1, wherein
the third capacitor reduces a harmonic frequency component included in a high frequency band in a radio frequency signal input to the first port.

9. The band pass filter of claim 1, wherein
the third capacitor bypasses a high frequency band signal in a radio frequency signal input to the first port to the ground.

10. A receiver module comprising:
a switch integrated circuit (IC) configured to switch a received radio frequency signal;
a band pass filter configured to pass a main frequency band in the radio frequency signal transmitted from the switch IC; and
a low noise amplifier configured to amplify a signal transmitted from the band pass filter,
wherein the band pass filter comprises:
a resonator including a first inductor and a first capacitor coupled in series between an input port and an output port;
a second capacitor connected between the input port and the output port, and coupled in parallel with the resonator; and
a third capacitor connected between one end of the second capacitor and a ground, and configured to perform a low pass filter function.

11. The receiver module of claim 10, wherein
the band pass filter further comprises a fourth capacitor coupled in series with the second capacitor between the input port and the output port and coupled in parallel with the resonator, and
the third capacitor is connected between a contact node of the second capacitor and the fourth capacitor and the ground.

12. The receiver module of claim 11, wherein the band pass filter further comprises:
a fifth capacitor connected between the input port and the ground; and
a sixth capacitor connected between the output port and the ground.

13. The receiver module of claim 12, wherein
the fifth capacitor and the sixth capacitor are configured to perform the low pass filter function together with the third capacitor.

14. The receiver module of claim 10, wherein
the band pass filter further comprises a fourth capacitor connected between another end of the second capacitor and the ground.

15. The receiver module of claim 14, wherein
the fourth capacitor is configured to perform the low pass filter function together with the third capacitor.
